(19) United States
(12) Patent Application Publication
(10) Pub. No.: US 2025/0258443 A1
(43) Pub. Date: Aug. 14, 2025

(54) METHODS OF FABRICATING SEMICONDUCTOR DEVICES

(71) Applicant: Samsung Electronics Co., Ltd., Suwon-si (KR)

(72) Inventors: Young Kyun IM, Suwon-si (KR); Young Ho Hwang, Suwon-si (KR); Sun Young Yun, Suwon-si (KR); Jae Hong Lim, Suwon-si (KR); Chul Min Cho, Suwon-si (KR); Seok Heo, Suwon-si (KR)

(21) Appl. No.: 18/884,268

(22) Filed: Sep. 13, 2024

(30) Foreign Application Priority Data
Feb. 14, 2024 (KR) 10-2024-0020836

(51) Int. Cl. G03F 7/00; G03F 7/30; G03F 7/40; H01L 21/027

(52) U.S. Cl. CPC G03F 7/70875; G03F 7/30; G03F 7/40; H01L 21/027

(57) ABSTRACT

A method of fabricating a semiconductor device, the method comprising: forming a photoresist layer on an upper surface of a wafer; exposing a portion of the photoresist layer to light to form an exposed region of the photoresist layer and an unexposed region of the photoresist layer; etching a first portion of the exposed region by using a first developer having a first temperature; lowering a temperature of the photoresist layer by using cooling gas; and etching a second portion of the exposed region by using a second developer having a second temperature that is lower than the first temperature.

### CROSS-REFERENCE TO RELATED APPLICATIONS

This application claims priority from Korean Patent Application No. 10-2024-0020836 filed on Feb. 14, 2024 in the Korean Intellectual Property Office, and all the benefits accruing therefrom under 35 U.S.C. 119, the contents of which in its entirety are herein incorporated by reference.

### BACKGROUND OF THE INVENTION

### Technical Field

The present inventive concepts relate to semiconductor devices. Specifically, the present inventive concepts relate methods of fabricating semiconductor devices. More specifically, the present inventive concepts relate to methods of fabricating semiconductor devices using a developing apparatus.

### Description of Related Art

A development process in a photo process (of a semiconductor device manufacturing method) is a process of exposing a photoresist layer with (to) light and then etching an exposed portion of the photoresist layer using a developer, thereby forming a photoresist pattern.

When using a high (e.g., a higher) temperature developer, a solubility of the photoresist layer increases, thereby reducing a development process time. However, in this case, a solubility of an unexposed portion of the photoresist layer may also increase, causing the photoresist pattern to be formed inaccurately (e.g., undesirably). Additionally, when using a low (e.g., a lower) temperature developer, the unexposed portion of the photoresist layer may be prevented from dissolving (e.g., may be less dissolved), but the development process time may increase. To solve these problems, research is being conducted to improve the accuracy of the photoresist pattern while reducing the development process time.

### SUMMARY OF THE INVENTION

One of the purposes that the present inventive concepts aim to achieve is to provide methods of fabricating semiconductor devices in which a portion of an exposed region is etched using a first developer having a first temperature, and then, the remaining portion of the exposed region is etched using a second developer having a second temperature lower than the first temperature, thereby reducing a development process time.

In addition, another purpose that the present inventive concepts seek to achieve is to provide methods of fabricating semiconductor devices in which a portion of an exposed region is etched using a first developer having a first temperature, and then, the remaining portion of the exposed region is etched using a second developer having a second temperature lower than the first temperature, thereby improving photoresist pattern accuracy.

According to some embodiments of the present disclosure, there is provided a method of fabricating a semiconductor device, the method comprising: forming a photoresist layer on an upper surface of a wafer; exposing a portion of the photoresist layer to light to form an exposed region of the photoresist layer and an unexposed region of the photoresist layer; etching a first portion of the exposed region by using a first developer having a first temperature; lowering a temperature of the photoresist layer by using cooling gas; and etching a second portion of the exposed region by using a second developer having a second temperature that is lower than the first temperature.

According to some embodiments of the present disclosure, there is provided a method of fabricating a semiconductor device, the method comprising: forming a photoresist layer on an upper surface of a wafer; exposing a portion of the photoresist layer to light to form an exposed region of the photoresist layer; producing a first developer having a first temperature by adjusting a temperature of a developer by using a temperature adjuster that is connected to a first nozzle through a pipe, wherein the first nozzle is above the upper surface of the wafer; providing the first developer to the photoresist layer from the first nozzle; etching a portion of the exposed region by using the first developer; producing a second developer having a second temperature by adjusting the temperature of the developer by using the temperature adjuster, wherein the second temperature is lower than the first temperature; providing the second developer to the photoresist layer from the first nozzle; and etching a remaining portion of the exposed region by using the second developer.

According to some embodiments of the present disclosure, there is provided a method of fabricating a semiconductor device, the method comprising: forming a photoresist layer on an upper surface of a wafer; exposing a portion of the photoresist layer to light to form an exposed region of the photoresist layer; lowering a temperature of the photoresist layer to a first temperature; producing a first developer having the first temperature by adjusting a temperature of a developer by using a temperature adjuster that is connected to a first nozzle through a pipe, wherein the first nozzle is above the upper surface of the wafer; etching a portion of the exposed region by providing the first developer to the photoresist layer through the first nozzle; heating the wafer to maintain the temperature of the photoresist layer at the first temperature while the etching the portion of the exposed region; drying and removing the first developer by providing cooling gas to the photoresist layer through a second nozzle that is above the upper surface of the wafer; lowering the temperature of the photoresist layer by using the cooling gas while the drying and removing the first developer by the providing cooling gas to the photoresist layer through the second nozzle; producing a second developer having a second temperature by adjusting the temperature of the developer by using the temperature adjuster, wherein the second temperature is lower than the first temperature; and etching a remaining portion of the exposed region by providing the second developer to the photoresist layer through the first nozzle.

Purposes according to the present inventive concepts are not limited to the above-mentioned purposes. Other purposes and advantages according to the present inventive concepts that are not mentioned may be understood based on following descriptions, and may be more clearly understood based on embodiments according to the present inventive concepts. Further, it will be easily understood that the purposes and advantages according to the present inventive concepts may be realized using means shown in the claims or combinations thereof.

Specific details of other embodiments may be included in the detailed descriptions in conjunction with drawings.

### BRIEF DESCRIPTION OF DRAWINGS

The above and other aspects and features of the present inventive concepts will become more apparent by describing in detail some embodiments thereof with reference to the attached drawings, in which:

FIG. 1 is a diagram for illustrating a developing apparatus according to some embodiments of the present inventive concepts;

FIG. 2 is a diagram for illustrating a developing apparatus according to some embodiments of the present inventive concepts;

FIG. 3 is a flow chart for illustrating a method of fabricating a semiconductor device according to some embodiments of the present inventive concepts using the developing apparatus as shown in FIG. 1 or FIG. 2;

FIG. 4 to FIG. 18 are diagrams of intermediate steps of a method of fabricating a semiconductor device and intermediate structures formed by the intermediate steps according to some embodiments of the present inventive concepts using the developing apparatus as shown in FIG. 1 or FIG. 2; and

FIG. 19 and FIG. 20 are diagrams of intermediate structures corresponding to intermediate steps of a method of fabricating a semiconductor device according to some embodiments of the present inventive concepts using the developing apparatus as shown in FIG. 1 or FIG. 2.

### DETAILED DESCRIPTION OF THE INVENTION

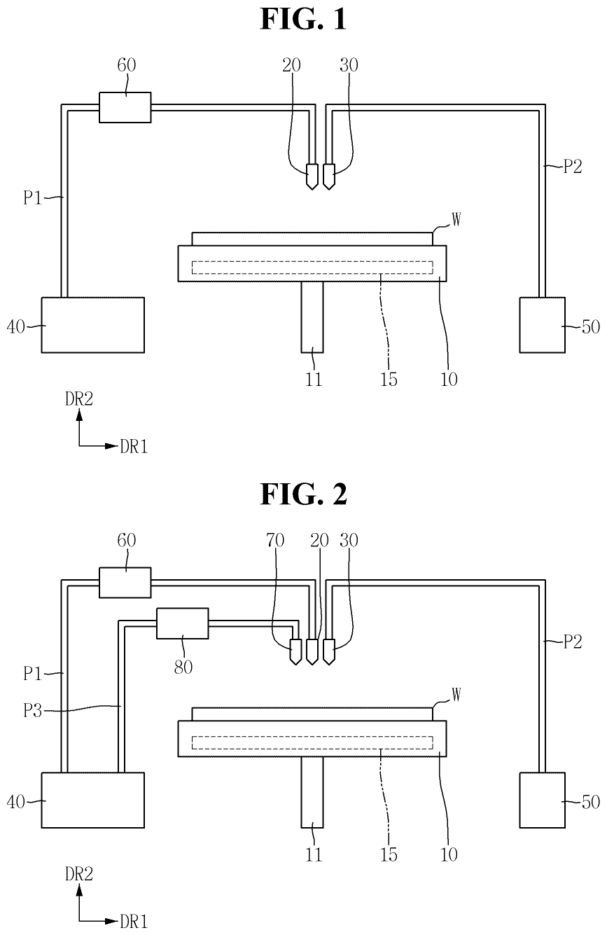

Hereinafter, a developing apparatus according to some embodiments of the present inventive concepts is described with reference to FIG. 1.

FIG. 1 is a diagram for illustrating the developing apparatus according to some embodiments of the present inventive concepts.

Referring to FIG. 1, the developing apparatus according to some embodiments of the present inventive concepts may include a stage 10, a support 11, a wafer heater 15, a first nozzle 20, a second nozzle 30, a developer storage 40, a cooling gas storage 50, a first temperature adjuster 60, a first pipe P1, and a second pipe P2.

The stage 10 may be a part on which a wafer W is positioned while the development process is performed. For example, the wafer W may be located on an upper surface of the stage 10. Hereinafter, a horizontal direction DR1 may be defined as a direction parallel to the upper surface of the stage 10. A vertical direction DR2 may be defined as a direction perpendicular to the upper surface of the stage 10. That is, the vertical direction DR2 may be defined as a direction perpendicular to the horizontal direction DR1.

The support 11 may be connected to a lower surface of the stage 10. The support 11 may be configured to rotate the stage 10. For example, the wafer heater 15 may be disposed inside the stage 10. However, the present inventive concepts are not limited thereto. In further some embodiments, the wafer heater 15 may be disposed outside (e.g., under or below) the stage 10.

The wafer heater 15 may heat the wafer W located on the upper surface of the stage 10. For example, the wafer heater 15 may heat (may be configured to target to heat) a lower surface of the wafer W. For example, the wafer heater 15 may heat (may be configured to target to heat) an edge region of the wafer W. In this case, the wafer heater 15 may heat the edge region of the wafer W located on the upper surface of the wafer W. In some embodiments, the wafer heater 15 may heat (may be configured to target to heat) an entirety of the wafer W. In this case, the wafer heater 15 may heat the entirety of the wafer W located on the upper surface of the wafer W.

The first nozzle 20 may be disposed on (above) the upper surface of the stage 10. That is, the first nozzle 20 may be disposed on (above) the upper surface of the wafer W located on the upper surface of the stage 10. The first nozzle 20 may be spaced apart from the upper surface of the wafer W in the vertical direction DR2. The first nozzle 20 may provide a first developer (130 in FIG. 7 and FIG. 9) to the wafer W. Additionally, the first nozzle 20 may provide a second developer (150 in FIG. 15 and FIG. 17) to the wafer W. For example, the first developer (130 in FIG. 7 and FIG. 9) may have a first temperature. The second developer (150 in FIG. 15 and FIG. 17) may have a second temperature lower than the first temperature. For example, the first temperature may range from (about) 20° C. to (about) 40°° C. For example, the second temperature may range from (about) 5° C. to (about) 25° C. The values of first temperature and the second temperature are not limited to the above-noted values. Herein, a temperature may refer to a temperature with a deviation. For example, when the first temperature is set at 30° C., the first temperature may be (slightly) deviated, for example, from 29.9°° C. to 30.1° C. (depending on the temperature resolution of the temperature adjuster (e.g., the first temperature adjuster 60)).

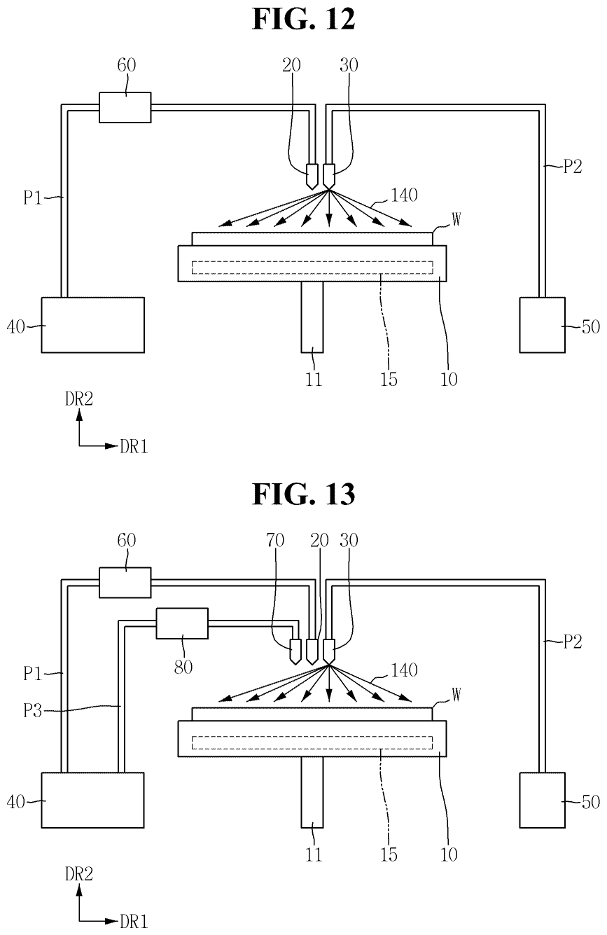

The second nozzle 30 may be disposed on (above) the upper surface of the stage 10. That is, the second nozzle 30 may be disposed on (above) the upper surface of the wafer W located on the upper surface of the stage 10. The second nozzle 30 may be spaced apart from the upper surface of the wafer W in the vertical direction DR2. For example, the second nozzle 30 may be spaced apart from the first nozzle 20 in the horizontal direction DR1. The second nozzle 30 may provide a cooling gas (140 in FIG. 12 to FIG. 14) to the wafer W. For example, the cooling gas (140 in FIG. 12 to FIG. 14) may include nitrogen (N₂). However, the present inventive concepts are not limited thereto. In some embodiments, the cooling gas (140 in FIG. 12 to FIG. 14) may include an inert gas such as helium (He) and/or argon (Ar).

The developer storage 40 may be configured to store therein the developer. The developer storage 40 may be connected to the first nozzle 20 through the first pipe P1. The first temperature adjuster 60 may be connected to the first pipe P1. The first temperature adjuster 60 may be connected to the developer storage 40 through the first pipe P1. Additionally, the first temperature adjuster 60 may be connected to the first nozzle 20 through the first pipe P1. The developer stored in the developer storage 40 may be provided to the first temperature adjuster 60 through the first pipe P1.

For example, a temperature of the developer provided from the developer storage 40 to the first temperature adjuster 60 may be adjusted to the first temperature using (by or by using) the first temperature adjuster 60. That is, the first temperature adjuster 60 may be configured to adjust the temperature of the developer to produce the first developer (130 in FIG. 7 and FIG. 9) having (that is at) the first temperature. The first developer (130 in FIG. 7 and FIG. 9) produced using (by or by using) the first temperature adjuster 60 may be provided to the first nozzle 20 through the first pipe P1.

For example, a temperature of the developer provided from the developer storage 40 to the first temperature adjuster 60 may be adjusted to the second temperature using (by or by using) the first temperature adjuster 60. In other words, the first temperature adjuster 60 may be configured to adjust the temperature of the developer to produce the second developer (150 in FIG. 15 and FIG. 17) having (that is at) the second temperature. The second developer (150 in FIG. 15 and FIG. 17) produced using (by or by using) the first temperature adjuster 60 may be provided to the first nozzle 20 through the first pipe P1.

The cooling gas storage 50 may be configured to store therein the cooling gas (140 in FIG. 12 to FIG. 14). The cooling gas storage 50 may be connected to the second nozzle 30 through the second pipe P2. The cooling gas (140 in FIG. 12 to FIG. 14) stored in the cooling gas storage 50 may be provided to the second nozzle 30 through the second pipe P2.

Hereinafter, with reference to FIG. 2, a developing apparatus according to some embodiments of the present inventive concepts is described. Following description focuses on differences thereof from the developing apparatus as shown in FIG. 1.

FIG. 2 is a diagram for illustrating a developing apparatus according to some embodiments of the present inventive concepts.

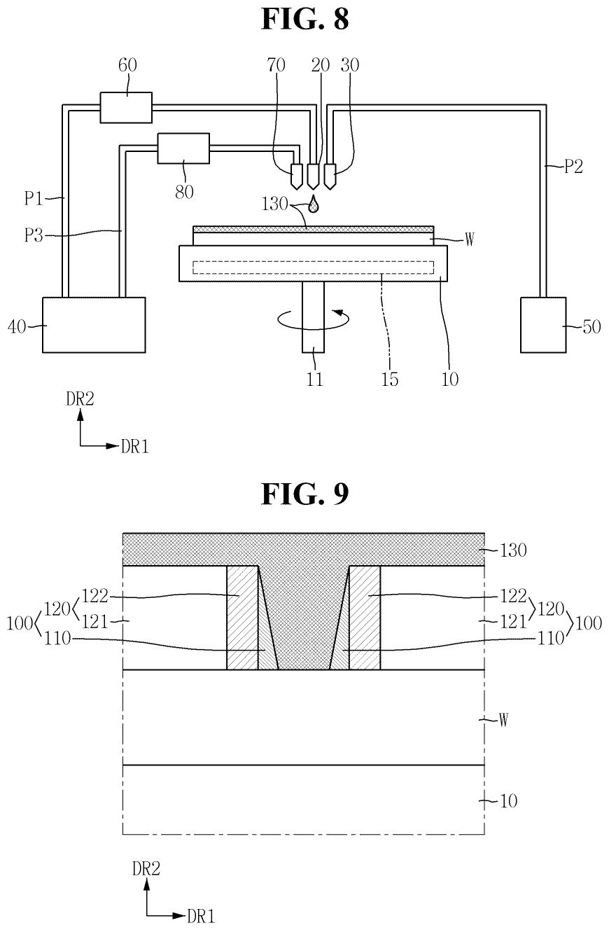

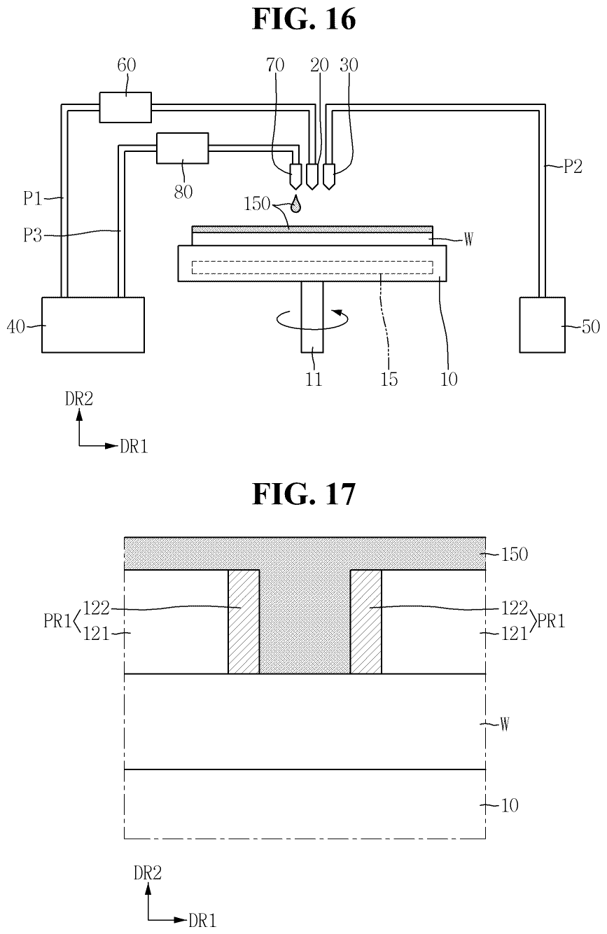

Referring to FIG. 2, in the developing apparatus according to some embodiments of the present inventive concepts, the first developer (130 in FIG. 8 and FIG. 9) and the second developer (150 in FIG. 16 and FIG. 17) may be provided to the wafer W through different nozzles.

For example, the first nozzle 20 may be configured to provide the first developer (130 in FIG. 7 and FIG. 9) to the wafer W. The developer storage 40 may be connected to the first nozzle 20 through the first pipe P1. The first temperature adjuster 60 may be connected to the first pipe P1. For example, the temperature of the developer provided from the developer storage 40 to the first temperature adjuster 60 may be adjusted to the first temperature using (by or by using) the first temperature adjuster 60 (to produce the first developer). The first developer (130 in FIG. 8 and FIG. 9) produced using (by or by using) the first temperature adjuster 60 may be provided to the first nozzle 20 through the first pipe P1.

For example, a third nozzle 70 may be disposed on (above) the upper surface of the stage 10. That is, the third nozzle 70 may be disposed on (above) the upper surface of the wafer W located on the upper surface of the stage 10. The third nozzle 70 may be spaced apart from the upper surface of the wafer W in the vertical direction DR2. For example, the third nozzle 70 may be spaced apart from each of the first nozzle 20 and the second nozzle 30 in the horizontal direction DR1. The third nozzle 70 may be configured to provide the second developer (150 in FIG. 15 and FIG. 17) to the wafer W.

The developer storage 40 may be connected to the third nozzle 70 through a third pipe P3. The second temperature adjuster 80 may be connected to the third pipe P3. The second temperature adjuster 80 may be connected to the developer storage 40 through the third pipe P3. Furthermore, the second temperature adjuster 80 may be connected to the third nozzle 70 through the third pipe P3.

For example, the temperature of the developer provided from the developer storage 40 to the second temperature adjuster 80 may be adjusted to the second temperature using (by or by using) the second temperature adjuster 80. That is, the second temperature adjuster 80 may be configured to produce the second developer (150 in FIG. 16 and FIG. 17) with the second temperature by adjusting the temperature of the developer provided from the developer storage 40 to the second temperature adjuster 80. The second developer (150 in FIG. 16 and FIG. 17) produced using (by or by using) the second temperature adjuster 80 may be provided to the third nozzle 70 through the third pipe P3.

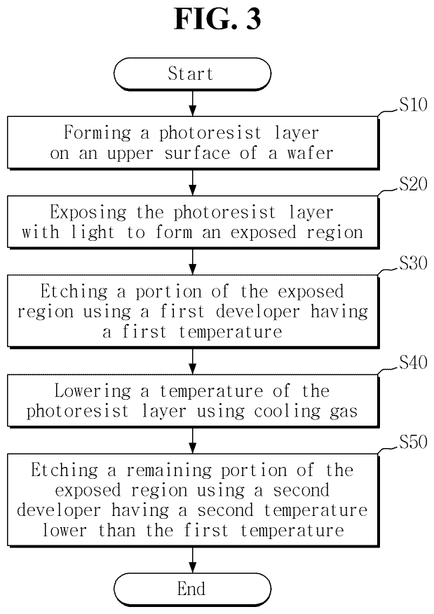

Hereinafter, a method of fabricating a semiconductor device according to some embodiments of the present inventive concepts is described with referring to FIG. 3 to FIG. 18.

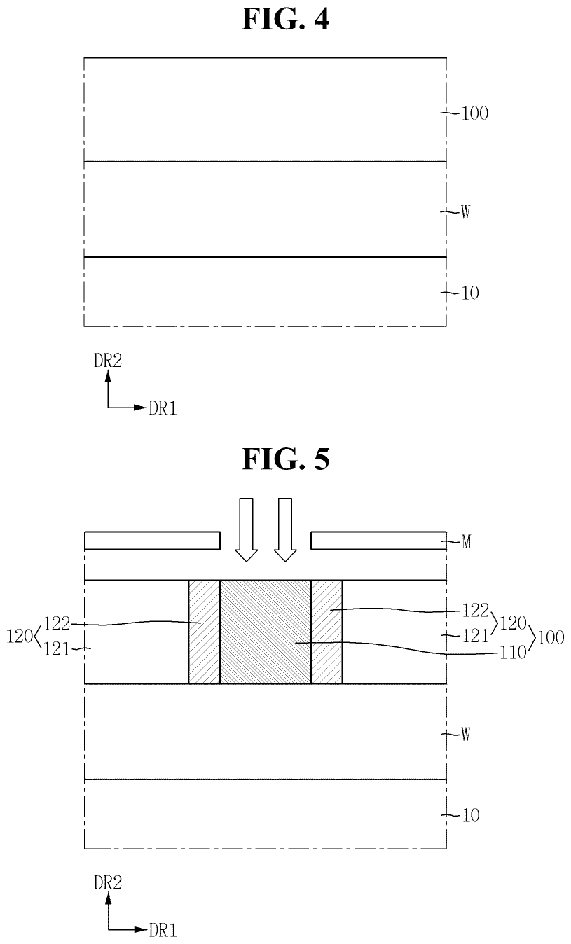

FIG. 3 is a flow chart for illustrating a method of fabricating a semiconductor device according to some embodiments of the present inventive concepts using the developing apparatus as shown in FIG. 1 or FIG. 2. FIG. 4 to FIG. 18 are diagrams of intermediate steps of a method of fabricating a semiconductor device and intermediate structures formed by the intermediate steps according to some embodiments of the present inventive concepts using the developing apparatus as shown in FIG. 1 or FIG. 2.

Referring to FIG. 3 and FIG. 4, a photoresist layer 100 may be formed on the upper surface of the wafer W in S10. Subsequently, the wafer W having the photoresist layer 100 formed thereon may be provided on the upper surface of the stage 10 in either the developing apparatus as shown in FIG. 1 or the developing apparatus as shown in FIG. 2.

Referring to FIG. 3 and FIG. 5, a photo mask M may be formed on an upper surface of the photoresist layer 100 in either the developing apparatus as shown in FIG. 1 or the developing apparatus as shown in FIG. 2. For example, the photo mask M may be spaced apart from the upper surface of the photoresist layer 100 in the vertical direction DR2.

Subsequently, an exposure process may be performed on the photoresist layer 100 using the photomask M as a mask. An exposed region 110 may be formed by exposing (at least a portion of) the photoresist layer 100 (to light) in S20. For example, the photoresist layer 100 may include the exposed region 110 and an unexposed region 120. For example, the unexposed region 120 may include a first region 121 and a second region 122. The first region 121 may be defined as a region spaced apart from the exposed region 110 in the horizontal direction DR1. The second region 122 may be defined as a region formed between the exposed region 110 and the first region 121. The second region 122 may be formed (directly) adjacent to each of the exposed region 110 and the first region 121. For example, the first region 121 may be spaced apart from the exposed region 110 by the second region 122.

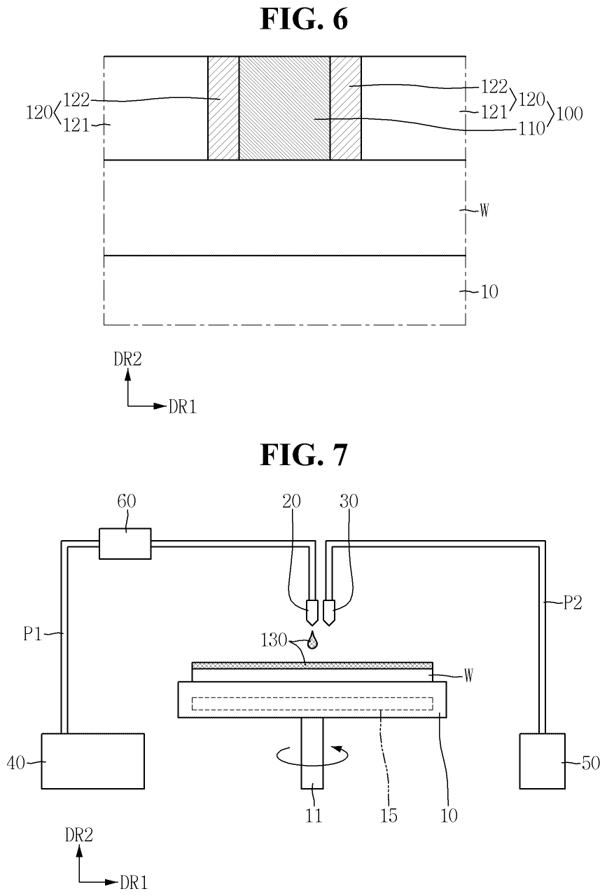

Referring to FIG. 6, in either the developing apparatus as shown in FIG. 1 or the developing apparatus as shown in FIG. 2, the exposure process has been completed, and then, the photo mask (M in FIG. 5) may be removed. Subsequently, a temperature of the photoresist layer 100 may be set at (e.g., reduced to) the first temperature. For example, the first temperature may range from (around) 20°° C. to (around) 40° C., but the value of the first temperature is not limited thereto.

Referring to FIG. 3, FIG. 7 to FIG. 9, in either the developing apparatus as shown in FIG. 1 or the developing apparatus as shown in FIG. 2, (at least) a portion of the exposed region 110 may be removed (etched) using (by or by using) the first developer 130 having (that is at) the first temperature in S30.

For example, the developer stored in the developer storage 40 may be provided to the first temperature adjuster 60 through the first pipe P1. The first temperature adjuster 60 may produce the first developer 130 by adjusting the developer provided from the developer storage 40 to the first temperature. For example, the first temperature may range from (about) 20° C. to (about) 40° C., but the value of the first temperature is not limited thereto. The first developer 130 whose the temperature has been adjusted to the first temperature by the first temperature adjuster 60 may be provided to the first nozzle 20 through the first pipe P1. The first nozzle 20 may provide the first developer 130 on the upper surface of the photoresist layer 100. While the first developer 130 is provided on the upper surface of the photoresist layer 100, the stage 10 may be rotated. Thus, the first developer 130 may be applied to an entirety of an upper surface of the photoresist layer 100.

At least a portion of the exposed region 110 may be removed (e.g., etched) using (by or by using) the first developer 130 having (that is at) the first temperature applied on the upper surface of the photoresist layer 100. A portion of the exposed region 110 may remain without being removed (e.g., etched) by the first developer 130. For example, the remaining portion of the exposed region 110 may contact a sidewall of the second region 122 of the unexposed region 120. For example, the upper surface of the wafer W may be exposed toward a sidewall of the remaining portion of the exposed region 110. That is, a portion of the exposed region 110 may be removed (e.g., etched) so that the first developer 130 is in contact with (a portion of) the upper surface of the wafer W (and a sidewall of the remaining portion of the exposed region 110). For example, referring to FIG. 9, a width in the horizontal direction DR1 between opposite sidewalls of the remaining portion of the exposed region 110 in the horizontal direction DR1 may (continuously) decrease as the remaining portion of the exposed region 110 approaches the upper surface of the wafer W.

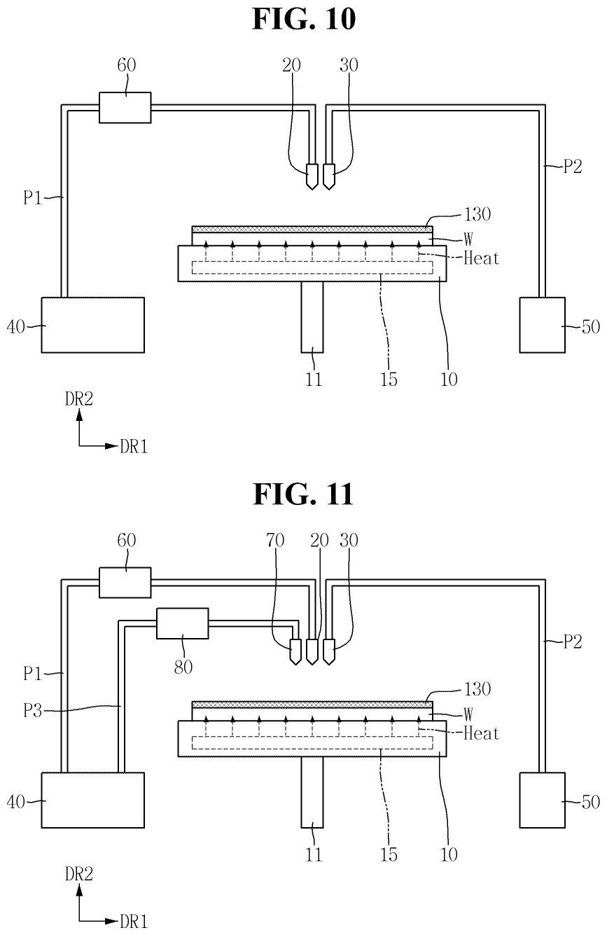

Referring to FIG. 10 and FIG. 11, while, in either the developing apparatus as shown in FIG. 1 or the developing apparatus as shown in FIG. 2, a portion of the exposed region (110 in FIG. 9) is etched using (by or by using) the first developer 130, a temperature of the photoresist layer (100 in FIG. 9) may be maintained at the first temperature (e.g., increased to the first temperature) by heating the wafer W.

For example, a heating process Heat on the wafer W may be performed using (by or by using) the wafer heater 15. The wafer heater 15 may increase the temperature of the photoresist layer (100 in FIG. 9) by heating the wafer W (to maintain the temperature of the photoresist layer 100 at the first temperature). In some embodiments, the wafer heater 15 may heat an entirety of the wafer W to increase the temperature of the photoresist layer (100 in FIG. 9) (to maintain the temperature of the photoresist layer 100 at the first temperature). In further some embodiments, the wafer heater 15 may increase the temperature of the edge region of the photoresist layer (100 in FIG. 9) by heating the edge region of the wafer W (to maintain the temperature of the photoresist layer 100 at the first temperature).

While the portion of the exposed region (110 in FIG. 9) is removed (e.g., etched) using (by or by using) the first developer 130, the stage 10 may be rotated. When the wafer W is not heated, the temperature of the photoresist layer (100 in FIG. 9) decreases (lower than the first temperature) due to the rotation of the stage 10, thereby lowering a speed of the etching process on the exposed region (110 in FIG. 9) using the first developer 130. Furthermore, a side effect may occur due to a difference between temperatures of the photoresist layer (100 in FIG. 9) and the first developer 130. For example, the temperature of the photoresist layer 100 may be decreased lower than the first temperature during the removal of at least a portion of the exposed region 110 of the photoresist layer 100 because the rotation of the stage 10 may cool down the temperature of the photoresist layer 100.

To solve this problem, a method for fabricating a semiconductor device according to some embodiments of the present inventive concepts may heat the wafer W (to maintain the first temperature) while the portion of the exposed region (110 in FIG. 9) is removed (etched) using (by or by using) the first developer 130. As a result, the speed of the etching process of the exposed region (110 in FIG. 9) using the first developer 130 may be maintained (prevented from decreasing). Furthermore, the side effect caused by the difference between the temperatures of the photoresist layer (100 in FIG. 9) and the first developer 130 may be reduced (e.g., prevented).

Referring to FIG. 12 to FIG. 14, the temperature of the photoresist layer 100 may be reduced using (by or by using) the cooling gas 140, in either the developing apparatus as shown in FIG. 1 or the developing apparatus as shown in FIG. 2 in S40.

For example, the cooling gas 140 stored in the cooling gas storage 50 may be provided to the second nozzle 30 through the second pipe P2. The second nozzle 30 may provide the cooling gas 140 on the upper surface of the wafer W (on the upper surface of the photoresist layer 100). The temperature of the photoresist layer 100 may be lowered by using the cooling gas 140 provided on the upper surface of the wafer W (on the upper surface of the photoresist layer 100). For example, the temperature of the photoresist layer 100 may be lowered to a temperature lower than the first temperature. Furthermore, while the temperature of the photoresist layer 100 is lowered using the cooling gas 140, the first developer (130 in FIG. 9) may be dried and removed using (by or by using) the cooling gas 140. That is, using the cooling gas 140, the temperature of the photoresist layer 100 may be lowered and at the same time, the first developer (130 in FIG. 9) may be removed. As a result, the sidewall of the remaining portion of the exposed region 110 may be exposed.

For example, the cooling gas (140 in FIG. 12 to FIG. 14) may include nitrogen (N₂). However, the present inventive concepts are not limited thereto. In further some embodiments, the cooling gas (140 in FIG. 12 to FIG. 14) may include an inert gas such as helium (He) and/or argon (Ar).

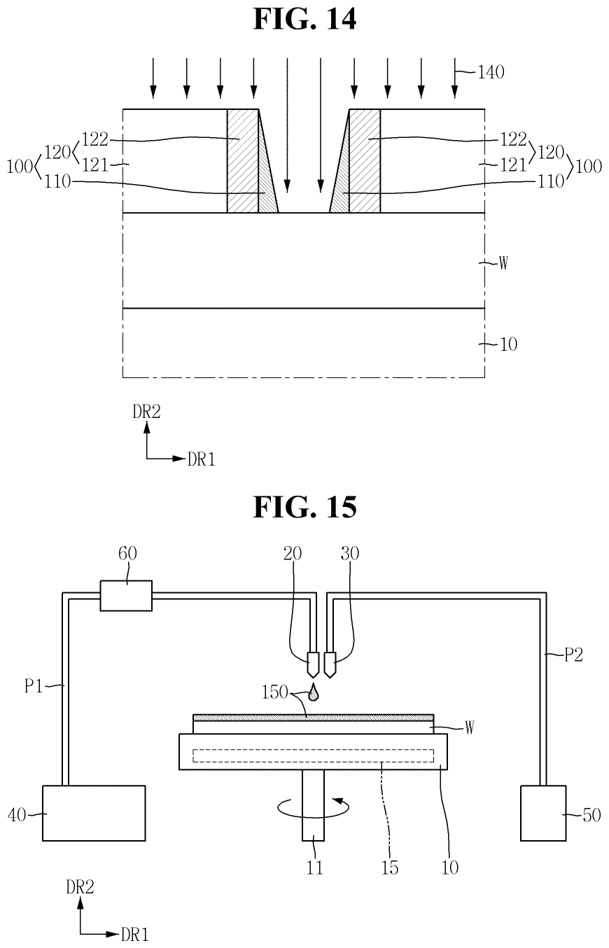

Referring to FIG. 15 to FIG. 17, in either the developing apparatus as shown in FIG. 1 or the developing apparatus as shown in FIG. 2, the remaining potion of the exposed region (110 in FIG. 14) may be removed (e.g., etched) in S50.

For example, referring to FIG. 15 and FIG. 17, in the developing apparatus as shown in FIG. 1, the developer stored in the developer storage 40 may be provided to the first temperature adjuster 60 through the first pipe P1. The first temperature adjuster 60 may produce the second developer 150 by adjusting the developer provided from the developer storage 40 to the second temperature lower than the first temperature. For example, the second temperature may range from (about) 5°° C. to (about) 25° C., but the value of the second temperature is not limited thereto.

The second developer 150 whose the temperature has been adjusted to the second temperature by the first temperature adjuster 60 may be provided to the first nozzle 20 through the first pipe P1. The first nozzle 20 may provide the second developer 150 on (the upper surface of) the photoresist layer (100 in FIG. 14). In some embodiments, the second developer 150 may be provided on the upper surface of the unexposed region 120 of the photoresist layer 100, a sidewall of the remaining portion of the exposed region 110, and a portion of the upper surface of the wafer W. While the second developer 150 is provided on (the upper surface of) the photoresist layer (100 in FIG. 14), the stage 10 may be rotated. Thus, the second developer 150 may be applied to an entirety of the upper surface of the photoresist layer (100 in FIG. 14).

The remaining portion of the exposed region (110 in FIG. 14) may be removed (e.g., etched) using (by or by using) the second developer 150 with the second temperature applied on the upper surface of the photoresist layer (100 in FIG. 14) (on the upper surface of the unexposed region 120 of the photoresist layer 100, a sidewall of the remaining portion of the exposed region 110, and a portion of the upper surface of the wafer W). In this case, the unexposed region (120 in FIG. 14) is not etched. For example, while the remaining portion of the exposed region (110 in FIG. 14) is removed (e.g., etched) using (by or by using) the second developer 150 with the second temperature, the second region 122 of the unexposed region (120 in FIG. 14) is not etched. In some embodiments, the first region 121 and the second region 122 of the unexposed region 120 may not be removed by the second developer 150. The first region 121 and the second region 122 remaining without being etched by the second developer 150 may be defined as a photoresist pattern PR1.

For example, referring to FIG. 16 and FIG. 17, in the developing apparatus as shown in FIG. 2, the developer stored in the developer storage 40 may be provided to the second temperature adjuster 80 through the third pipe P3. The second temperature adjuster 80 may produce the second developer 150 by adjusting the developer provided from the developer storage 40 to the second temperature lower than the first temperature. For example, the second temperature may range from (about) 5° C. to (about) 25° C., but the value of the second temperature is not limited thereto.

The second developer 150 whose the temperature has been adjusted to the second temperature by the second temperature adjuster 80 may be provided to the third nozzle 70 through the third pipe P3. The third nozzle 70 may provide the second developer 150 on the upper surface of the photoresist layer (100 in FIG. 14). In some embodiments, the second developer 150 may be provided on the upper surface of the unexposed region 120 of the photoresist layer 100, a sidewall of the remaining portion of the exposed region 110, and a portion of the upper surface of the wafer W. While the second developer 150 is provided on (the upper surface of) the photoresist layer (100 in FIG. 14), the stage 10 may be rotated. Thus, the second developer 150 may be applied to an entirety of the upper surface of the photoresist layer (100 in FIG. 14).

The remaining portion of the exposed region (110 in FIG. 14) may be removed (e.g., etched) using (by or by using) the second developer 150 with the second temperature applied on the upper surface of the photoresist layer (100 in FIG. 14) (on the upper surface of the unexposed region 120 of the photoresist layer 100, a sidewall of the remaining portion of the exposed region 110, and a portion of the upper surface of the wafer W). In this case, the unexposed region (120 in FIG. 14) is not etched. For example, while the remaining portion of the exposed region (110 in FIG. 14) is removed (e.g., etched) using (by or by using) the second developer 150 with the second temperature, the second region 122 of the unexposed region (120 in FIG. 14) is not etched. In some embodiments, the first region 121 and the second region 122 of the unexposed region 120 may not be removed by the second developer 150. The first region 121 and the second region 122 remaining without being etched by the second developer 150 may be defined as a photoresist pattern PR1.

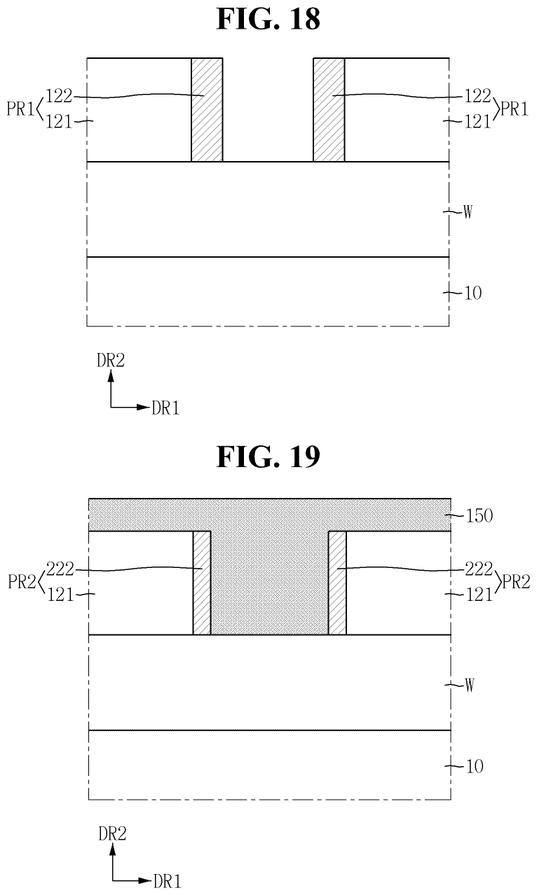

Referring to FIG. 18, the second developer (150 in FIG. 15 to FIG. 17) may be removed. Thus, the photoresist pattern PR1 may be formed on the upper surface of the wafer W.

The method for fabricating the semiconductor device according to some embodiments of the present inventive concepts may include etching (at least) a portion of the exposed region 110 using the first developer 130 having (that is at) the first temperature, and then etching the remaining portion of the exposed region 110 using the second developer 150 having (that is at) the second temperature, thereby forming the photoresist pattern PR1. The solubility of the exposed region 110 may be increased using the first developer 130 having (that is at) the first temperature, such that the process time for etching the portion of the exposed region 110 may be reduced. Furthermore, the remaining portion of the exposed region 110 using the second developer 150 having (that is at) the second temperature lower than the first temperature may be etched such that the unexposed region 120 is prevented from being etched, thereby improving accuracy of the photoresist pattern PR1. In other words, the method for fabricating the semiconductor device according to some embodiments of the present inventive concepts may improve the accuracy of the photoresist pattern while reducing the development process time.

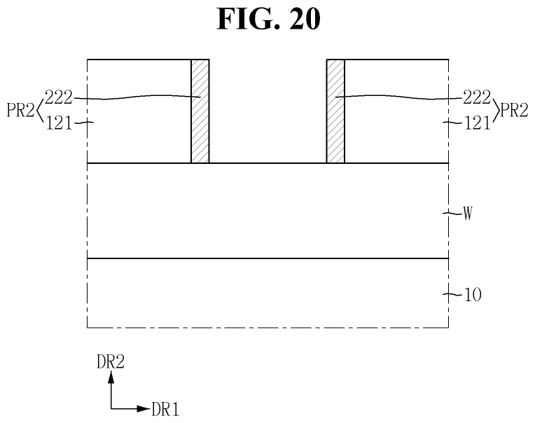

Hereinafter, with reference to FIG. 19 and FIG. 20, a method of fabricating a semiconductor device according to some embodiments of the present inventive concepts is described. Following description focuses on differences thereof from the method of fabricating the semiconductor device as shown in FIG. 4 to FIG. 18.

FIG. 19 and FIG. 20 are diagrams of intermediate structures corresponding to intermediate steps of a method of fabricating a semiconductor device according to some embodiments of the present inventive concepts, using the developing apparatus as shown in FIG. 1 or FIG. 2.

Referring to FIG. 19, after performing the fabricating process as shown in FIG. 4 to FIG. 14, the remaining portion of the exposed region (110 in FIG. 14) may be removed (e.g., etched) using (by or by using) the second developer 150 having (that is at) the second temperature lower than the first temperature in either the developing apparatus as shown in FIG. 1 or the developing apparatus as shown in FIG. 2,

For example, while the remaining portion of the exposed region (110 in FIG. 14) is removed (e.g., etched), a portion of a sidewall of the second region (122 in FIG. 14) of the remaining unexposed region (120 in FIG. 14) may be etched. A portion of the second region 122 in FIG. 14 remaining without being removed (e.g., etched) by the second developer 150 may be defined as a second region 222 as shown in FIG. 19. The first region 121 and the second region 222 remaining without being removed (e.g., etched) by the second developer 150 may be defined as a photoresist pattern PR2.

Referring to FIG. 20, the second developer (150 in FIG. 19) may be removed. Thus, the photoresist pattern PR2 may be formed on the upper surface of the wafer W.

Although embodiments of the present inventive concepts have been described with reference to the accompanying drawings, the present inventive concepts are not limited to the above embodiments, but may be implemented in various different forms. A person skilled in the art may appreciate that the present inventive concepts may be practiced in various forms without changing the scope of the present inventive concepts. Therefore, it should be appreciated that the embodiments as described above is not restrictive but illustrative in all respects.

What is claimed is:

1. A method of fabricating a semiconductor device, the method comprising:
forming a photoresist layer on an upper surface of a wafer;
exposing a portion of the photoresist layer to light to form an exposed region of the photoresist layer and an unexposed region of the photoresist layer;
etching a first portion of the exposed region by using a first developer having a first temperature;
lowering a temperature of the photoresist layer by using cooling gas; and
etching a second portion of the exposed region by using a second developer having a second temperature that is lower than the first temperature.

2. The method of claim 1, further comprising:
drying and removing the first developer by using the cooling gas while the lowering the temperature of the photoresist layer by using the cooling gas.

3. The method of claim 1, wherein the first temperature is from 20° C. to 40° C., and the second temperature is from 5° C. to 25° C.

4. The method of claim 1, further comprising:
providing the first developer to the photoresist layer from a first nozzle that is above the upper surface of the wafer, before the etching the first portion of the exposed region; and
providing the cooling gas to the photoresist layer from a second nozzle that is above the upper surface of the wafer, before the lowering the temperature of the photoresist layer.

5. The method of claim 4, further comprising:
providing the second developer to the photoresist layer from the first nozzle, before the etching the second portion of the exposed region.

6. The method of claim 5, further comprising:
producing the first developer having the first temperature by adjusting a temperature of a developer by using a first temperature adjuster that is connected to the first nozzle through a first pipe, before the providing the first developer to the photoresist layer from the first nozzle; and
producing the second developer having the second temperature by adjusting the temperature of the developer by using the first temperature adjuster, before the providing the second developer to the photoresist layer from the first nozzle.

7. The method of claim 4, further comprising:
providing the second developer to the photoresist layer from a third nozzle that is above the upper surface of the wafer, before the etching the second portion of the exposed region.

8. The method of claim 7, further comprising:
producing the first developer having the first temperature by adjusting a temperature of a developer by using a first temperature adjuster that is connected to the first nozzle through a first pipe, before the providing the first developer to the photoresist layer from the first nozzle; and
producing the second developer having the second temperature by adjusting the temperature of the developer by using a second temperature adjuster connected to the third nozzle through a second pipe, before the providing the second developer to the photoresist layer from the third nozzle.

9. The method of claim 1, further comprising:
heating the wafer to increase the temperature of the photoresist layer while the etching the first portion of the exposed region by using the first developer.

10. The method of claim 9, wherein the heating the wafer includes heating an edge region of the wafer to increase a temperature of an edge region of the photoresist layer.

11. The method of claim 1, wherein the cooling gas includes nitrogen (N₂).

12. The method of claim 1, wherein the etching of the second portion of the exposed region by using the second developer having the second temperature includes maintaining the unexposed region of the photoresist layer without etching.

13. A method of fabricating a semiconductor device, the method comprising:
forming a photoresist layer on an upper surface of a wafer;
exposing a portion of the photoresist layer to light to form an exposed region of the photoresist layer;
producing a first developer having a first temperature by adjusting a temperature of a developer by using a temperature adjuster that is connected to a first nozzle through a pipe, wherein the first nozzle is above the upper surface of the wafer;
providing the first developer to the photoresist layer from the first nozzle;
etching a portion of the exposed region by using the first developer;
producing a second developer having a second temperature by adjusting the temperature of the developer by using the temperature adjuster, wherein the second temperature is lower than the first temperature;
providing the second developer to the photoresist layer from the first nozzle; and
etching a remaining portion of the exposed region by using the second developer.

14. The method of claim 13, further comprising:
after the etching the portion of the exposed region by using the first developer, lowering a temperature of the photoresist layer by providing cooling gas to the photoresist layer from a second nozzle that is above the upper surface of the wafer.

15. The method of claim 14, further comprising:
drying and removing the first developer by using the cooling gas while the lowering the temperature of the photoresist layer.

16. The method of claim 13, further comprising:
before the etching the portion of the exposed region by using the first developer, lowering a temperature of the photoresist layer to the first temperature.

17. The method of claim 13, further comprising:
heating the wafer to increase a temperature of the photoresist layer while the etching the portion of the exposed region by using the first developer.

18. The method of claim 17, wherein the heating the wafer includes heating an entirety of the wafer to increase a temperature of an entirety of the photoresist layer.

19. The method of claim 13, wherein the first temperature is from 20° C. to 40° C., and the second temperature is from 5° C. to 25° C.

20. A method of fabricating a semiconductor device, the method comprising:
forming a photoresist layer on an upper surface of a wafer;
exposing a portion of the photoresist layer to light to form an exposed region of the photoresist layer;
lowering a temperature of the photoresist layer to a first temperature;
producing a first developer having the first temperature by adjusting a temperature of a developer by using a temperature adjuster that is connected to a first nozzle through a pipe, wherein the first nozzle is above the upper surface of the wafer;
etching a portion of the exposed region by providing the first developer to the photoresist layer through the first nozzle;
heating the wafer to maintain the temperature of the photoresist layer at the first temperature while the etching the portion of the exposed region;
drying and removing the first developer by providing cooling gas to the photoresist layer through a second nozzle that is above the upper surface of the wafer;
lowering the temperature of the photoresist layer by using the cooling gas while the drying and removing the first developer by the providing cooling gas to the photoresist layer through the second nozzle;
producing a second developer having a second temperature by adjusting the temperature of the developer by using the temperature adjuster, wherein the second temperature is lower than the first temperature; and
etching a remaining portion of the exposed region by providing the second developer to the photoresist layer through the first nozzle.
